(19) United States
(12) Patent Application Publication
(10) Pub. No.: US 2024/0322053 A1
(43) Pub. Date: Sep. 26, 2024

(54) Photodiodes

(71) Applicant: X-FAB Global Services GmbH, Erfurt (DE)

(72) Inventors: Daniel Gäbler, Apolda (DE); Pablo Siles, Erfurt (DE); Qiang Ai, Kuching (MY); Tamer Abdulrahman, Evry (FR)

(21) Appl. No.: 18/609,890

(22) Filed: Mar. 19, 2024

(30) Foreign Application Priority Data
Mar. 20, 2023 (GB) 2304001.7
Jul. 12, 2023 (GB) 2310724.6
Sep. 25, 2023 (GB) 2314622.8

(51) Int. Cl. H01L 31/0216; H01L 27/144; H01L 31/0203; H01L 31/103; H01L 31/18

(52) U.S. Cl. CPC H01L 31/02164; H01L 27/1443; H01L 31/103; H01L 31/1876; H01L 31/0203

(57) ABSTRACT

An optical sensor comprises a first and a second photodiode. Each photodiode comprises a respective light sensitive area. The second photodiode further comprises a wavelength-selective absorption layer arranged to selectively attenuate incident light before the light enters the light sensitive area of the second photodiode. The wavelength-selective absorption layer characterized by a low optical absorption in a wavelength range of 300 to 1100 nm and a high optical absorption in a wavelength range of 200 to 275 nm. The photodiodes are configured to generate respective electrical currents in response to incident light, and the optical sensor is configured to determine a light level based on a discrepancy between the electrical current generated by the first photodiode and the electrical current generated by the second photodiode.

### TECHNICAL FIELD

The invention relates photodiodes, and in particular to photodiodes having a high sensitivity in the ultraviolet range.

### BACKGROUND

Photodiodes are used in a wide range of applications for detecting and measuring electromagnetic radiation. It is known that a noise level of an output signal of a photodiode can be improved by subtracting the current of a dark reference device (a similar photodiode which is insensitive to light) from the current of the photodiode. The reference device may be made insensitive to incident light by covering the light sensitive area of the device with an opaque material (for example a metal layer). However, there is a continued need for improvements to the sensitivity and durability of photodiodes.

### SUMMARY

Silicon-based photodiodes may have a wide sensitivity range, including visible light and ultraviolet (UV) light. In general, the responsivity of these photodiodes may be higher for visible light than for ultraviolet light. This can cause a problem when an optical sensor device employs such a photodiode for measuring low intensity levels of UV light—in particular when the light of interest has a wavelength shorter than 275 nm. This is because the signal of interest may be obscured by a high noise level caused by (even small amounts of) stray light at longer wavelengths (e.g. wavelengths longer than 275 nm).

To at least partly solve this problem, the present invention provides an improved optical sensor device and method of forming such as set out in the accompanying claims.

Specific embodiments are described below with reference to the drawings.

### BRIEF DESCRIPTION OF DRAWINGS

FIG. 1 shows a schematic cross section of a part of a semiconductor structure comprising a photodiode;

FIG. 2 shows a schematic cross section of a part of a photodiode;

FIG. 3 shows a graph of a doping profile of a photodiode;

FIG. 4A to 4F show a sequence of schematic diagrams illustrating a method of forming a photodiode;

FIG. 5 shows a schematic top view of a semiconductor structure comprising a photodiode;

FIG. 6 shows a flow diagram illustrating the steps of a method of forming a photodiode;

FIG. 7 illustrates a further semiconductor structure comprising a primary photodiode and a reference photodiode;

FIG. 8 shows a schematic cross section of a part of a further semiconductor structure comprising the reference photodiode of FIG. 7;

FIG. 9 shows a graph of an experimentally obtained spectral response of a photodiode; and

FIG. 10 shows a table of experimentally obtained spectral response values of a photodiode.

### DETAILED DESCRIPTION

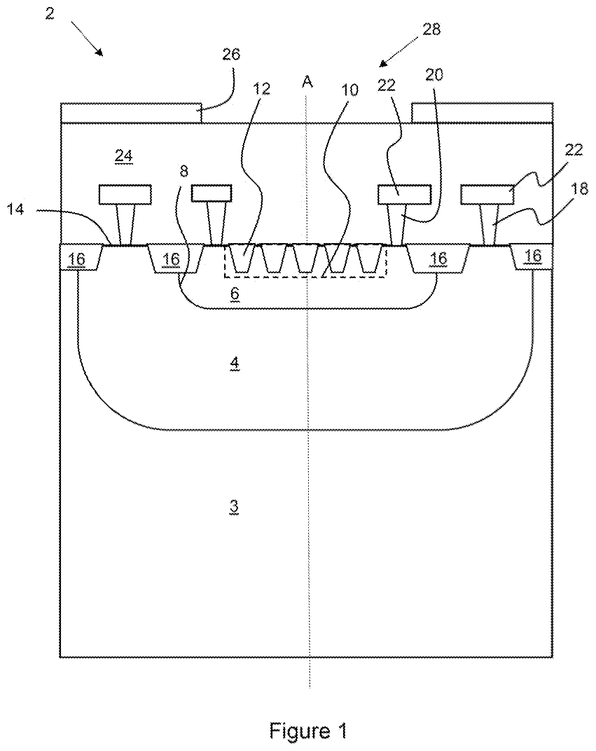

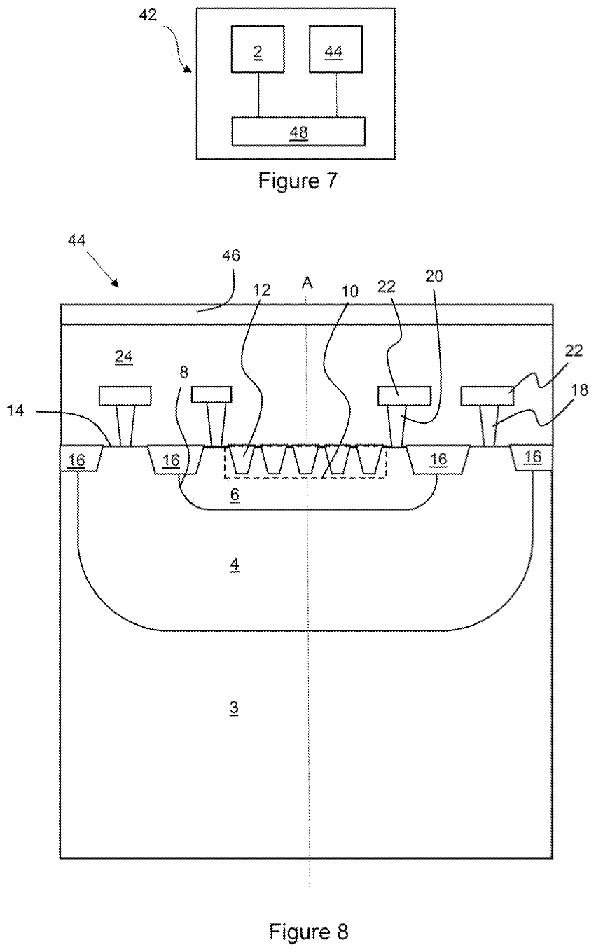

In overview, with reference to FIGS. 1 to 6, a method of forming a photodiode is described. The photodiode of FIGS. 1 to 6 is formed using a specific sequence of doping steps together with steps of forming an effective medium, which can reduce the chance of trapped charge carriers and thereby increase the sensitivity to UV light. Further, an embodiment of an optical sensor suitable for detecting low levels of light having a wavelength in a range of 200 to 275 nm is described with reference to FIGS. 7 to 10. As described in detail below, the optical sensor comprises a primary photodiode (e.g. the photodiode of FIGS. 1 to 6) as well as a reference photodiode (which has a similar sensitivity as the primary photodiode to light in a range of 275 to 1100 nm but which is essentially insensitive to light in a range of 200 to 275 nm). When in use, the current of the reference photodiode can be subtracted from the current of the primary photodiode to accurately determine the intensity of the incident light in the range of 200 to 275 nm.

Referring to FIGS. 1 to 6, a method of forming a photodiode using a specific sequence of doping steps together with the steps of forming an effective medium, which can reduce the chance of trapped charge carriers and thereby increase the sensitivity to UV light. In particular, the method comprises doping the sides and bottom of the trenches formed in the light sensitive area with two injection steps at different angles. A high doping concentration along the interface that steadily decreases towards the pn-junction pushes generated charge carriers away from the interface and towards the pn-junction (for detection).

FIG. 1 shows a photodiode 2 for UV detection. The photodiode 2 comprises a silicon wafer 3 comprising a first, n-doped, well 4 connected to the cathode of the photodiode 2, and a second, p-doped, well 6 connected to the anode of the photodiode 2. A pn-junction 8 is formed between the first well 4 and the second well 6. A patterned layer 10 being an effective medium comprising trenches 12 filled with oxide is located at the surface 14 of the silicon wafer 3 in the second well 6 in order to reduce reflection losses at the interface. The trenches 12 may be round or hexagonal holes arranged in an array to cover the light sensitive area associated with the pn-junction 8. The different well regions 4 and 6 are separated along the surface 14 by STI 16. A cathode contact 18 is connected to the first well 4, and an anode contact 20 is connected to the second well 6. Both contacts 18 and 20 are connected to a first metal layer 22 of a backend stack 24 of the photodiode 2. The backend stack 24 also comprises a passivation layer 26, with a UV window 28 overlapping the light sensitive area of the photodiode. Carriers generated by light absorbed in the p-doped well 6 are pushed by the inherent electric field due to the continuously falling doping profile towards the pn-junction 8. In particular, the doping concentration in the silicon at the interface between the trenches 12 and the silicon in the second well 6 is increased and continuously decreasing away from the interface, thereby reducing the risk of charge carriers being influenced at the interface. This influence can be due to changes in the electric field. For example, if the dielectric layers on top of the silicon change their trapped charge level.

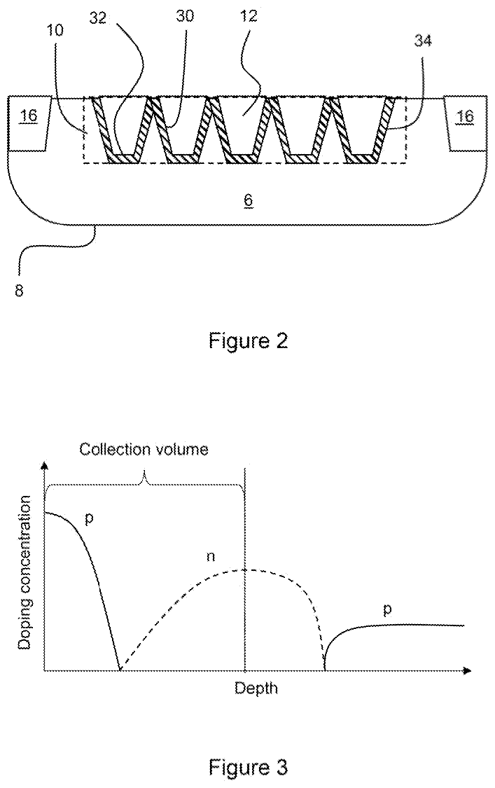

FIG. 2 shows an enlarged diagram of the second well 6 of the photodiode 2 shown in FIG. 1. The second well 6 comprises the patterned layer 10 comprising trenches 12 filled with oxide forming an effective medium with a refractive index between that of silicon and silicon oxide. Each trench 12 comprises sides 30 and a bottom 32. A layer 34 with increased doping concentration (relative to the rest of the well 6) runs along the interface (i.e. along the sides 30 and bottom 32 of the trenches 12) between the oxide in the trenches 12 and the silicon in the well 6. The layer with increased doping can reduce the risk of charge carriers generated close to the interface from becoming trapped.

FIG. 3 is schematic graph of the doping profile of the photodiode, with the doping concentration plotted against the depth along the line A shown in FIG. 1. The depth starts at the bottom of the trench 12 and runs into the epitaxial silicon of the wafer 3. The doping concertation falls continuously with depth in the p-doped well 6 towards the pn-junction 8. Charge carriers generated in this region will be pushed by the intrinsic electric field towards the pn-junction 8. The doping concentration decreases continuously from a peak concentration in the p-doped region towards the pn-junction, defining a collection volume, within which generated charge carriers are pushed to the pn-junction by the intrinsic electric field.

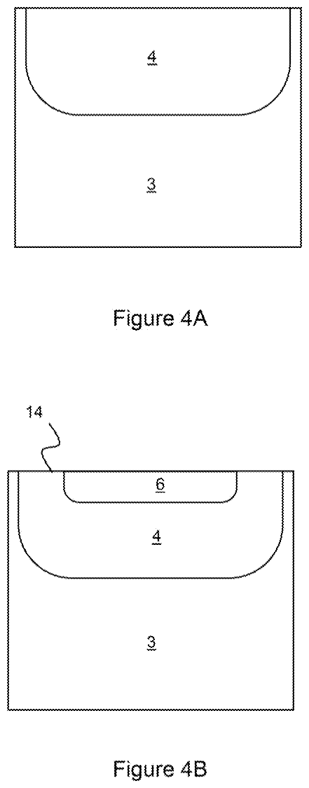

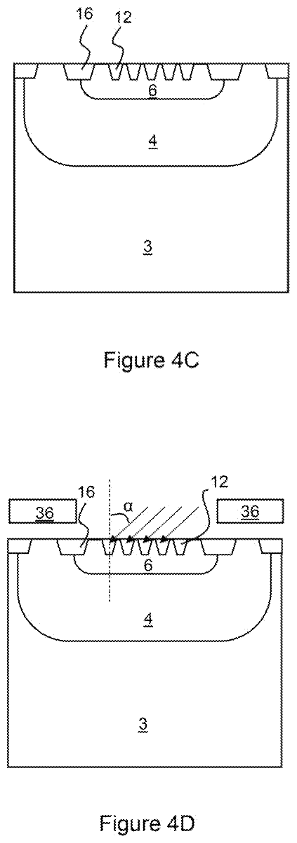

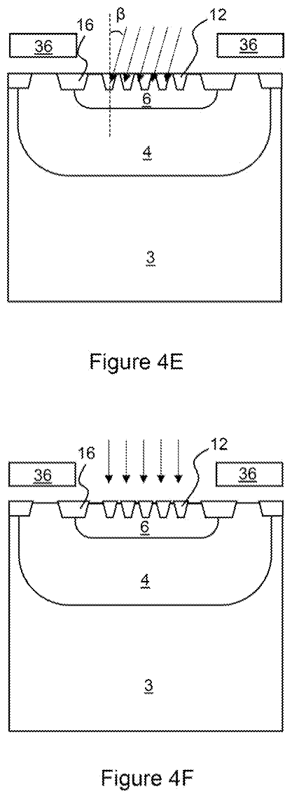

FIGS. 4A to 4F show a sequence of steps of a method of forming a photodiode.

FIG. 4A shows the wafer 3 with a first well 4 formed. The first well 4 is formed by injecting phosphorus (P) as dopant with an injection energy of 2 MeV to 3 MeV and so as to create a peak concentration in the range of 1e15 cm⁻³ to 1e19 cm⁻³.

FIG. 4B shows the wafer 3 after forming the second well 6 at the surface 14 of the wafer 3 before STI. The second well 6 is formed by injecting boron (B) with an injection energy of 10 keV to 20 keV and so as to create a peak concentration in the range of 1e14 cm⁻³ to 1e18 cm⁻³.

FIG. 4C shows the wafer 3 after forming trenches 12 and 16 in the surface 14 of the wafer 3 before filling with oxide. The trenches 16 for isolation and the (smaller) trenches 12 for forming an effective medium are formed using STI technology.

FIG. 4D shows a step of doping wherein BF2 dopants are injected at an angle α and with an injection energy of 20 keV and 30 keV using a mask 36. The doping step is performed after the STI liner oxide anneal (to form a thin layer of silicon oxide in the trenches 12), and before the STI oxide fill (deposition). The angle α of injection is in the range of 30° to 45° so as to dope the sides of the trenches 12. The wafer or injection source is rotated about a normal to the surface 14 and the injection repeated from at least four different directions, to provide uniform doping of the sides around the trenches 12. The injection angle α relative to the normal remains the same for each injection of the doping step.

FIG. 4E shows another step of doping wherein BF2 dopants are injected at another angle β, which is less than the injection angle α of the previous doping step. The doping step is performed before the STI oxide fill (deposition). The doping is performed with an injection energy in the range of 10 keV to 25 keV and is in general less than the injection energy of the previous doping step described in association with FIG. 4D above. The same mask 36 is used in this doping step, as it is the same region of the wafer 3 that is 20 being doped. The injection angle β is in the range of 1° to 10° in order to dope the bottom of the trenches 12. The wafer 3 or injection source is rotated about a normal to the surface 14 and the injection repeated from at least four different directions, to provide uniform doping of the bottom of the trenches 12. The injection angle β relative to the normal remains the same for each injection of the doping step. In an alternative embodiment, the injection angle β is set to 0°, in which case the wafer and source do not need to be rotated to achieve uniform doping.

FIG. 4F shows a further step of doping after filling the STI trenches 12, 16. The further step of doping increases the doping concentration at the surface of the semiconductor wafer between the trenches 12.

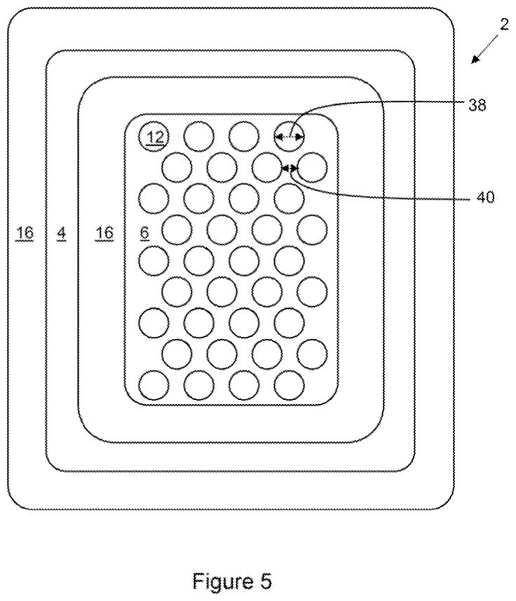

FIG. 5 shows a schematic top view of a part of a photodiode 2. The photodiode 2 comprises an array of trenches 12 being circular holes at the centre arranged to receive incident light. The holes have width 38 in the range of 220 nm to 350 nm and a spacing between adjacent holes in the range of 70 nm to 210 nm. In general the spacing between the trenches 12 is smaller than the width of the trenches 12. The central (anode) area, corresponding to the underlying p-doped well 6, is surrounded by isolation 16. Outside the isolation 16 is a ring (cathode) area, corresponding to the n-doped well 4, which is in turn surrounded by outer isolation 16. The photodiode may comprise a further outer p-doped anode ring and an n-doped guard ring (not shown).

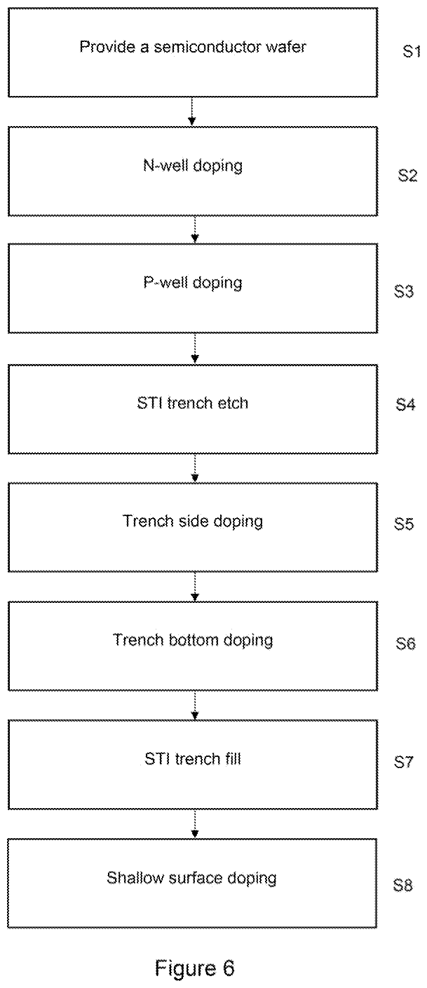

FIG. 6 shows a flow diagram of a method of forming a photodiode. The method comprises providing a semiconductor wafer (step S1). The wafer is a silicon wafer comprising a bulk silicon substrate and a doped epitaxial layer. A first doping step is performed to form an N-well in the epitaxial layer (step S2). After forming the N-well, a second step of doping is performed to form a P-well at the surface of the wafer and thereby form a pn-junction between the P-well and the N-well (step S3). After forming the pn-junction, an STI trench etch is performed to form a plurality of trenches in the P-well in the surface of the wafer (step S4). Before filling the trenches, a third doping step is performed at a relatively high angle with respect to a normal to the surface of the wafer to dope the sides of the trenches (step S5). A fourth doping step at a lesser angle is performed to dope the bottom of the trenches (step S6). After the fourth step of doping, the trenches are filled by oxide deposition (step S7). After filling the trenches, a fifth step of doping is performed to increase the doping in the p-doped well along the surface of the wafer (step S8). The method may comprise further steps as part of a backend of line (BEOL) process for forming anode and cathode contacts in order to apply a voltage across the pn-junction.

In general, the present disclosure provides a method of forming a photodiode. The method may be part of the manufacturing process of a photodetector or imaging device comprising one or more such photodiodes. The method is typically part of a complementary metal oxide semiconductor (CMOS) process, comprising a front end of line (FEOL) process for forming active semiconductor devices such as photodiodes and transistors, and a back end of line (BEOL) process for forming metal layers and contacts to the active semiconductor devices. The method comprises providing a semiconductor wafer, performing a first doping to form a first well in the wafer having a first type of doping, and performing a second doping to form a second well having a second type of doping, so as to form a pn-junction of the photodiode between the first well and the second well. The second step of doping may create a shallow p-well (or n-well) in a top layer of the wafer, which may be referred to as the active layer or diffusion layer and is typically a lightly doped epitaxial layer of silicon. The method further comprises performing a shallow trench isolation (STI) etch to form a plurality of trenches in the surface of the wafer in the second well.

High energy light (e.g. UV light) can change the charge in layers, which in turn can change the electrical field acting in the silicon. This effect causes degradation of photodiode performance from exposure to such light. The described method can provide a photodiode with a strong doping related field, which can lower or completely compensate this effect from UV exposure.

The method comprises performing a third doping by injecting dopants at a first angle relative to the surface of the wafer in order to increase a doping concentration of the second type of doping at along the sides of the trenches in the second well, and performing a fourth doping by injecting dopants at a second angle relative to the surface of the wafer in order to increase a doping concentration of the second type of doping at the bottom of the trenches in the second well. The third and fourth doping are performed after etching the trenches in the semiconductor wafer but before filling the trenches with STI material to provide a more even doping along the interface of the trenches. The method further comprises performing a fifth doping to increase a doping concentration of the second type of doping at the surface of the semiconductor wafer between the trenches in the second well, and forming a first contact for contacting the first well and forming a second contact for contacting the second well in order to apply a voltage across the pn-junction when in use. The contact formation may be part of a CMOS BEOL process further comprising forming a backend stack comprising a plurality of metal layers separated by interdielectric layers.

The first angle may be in the range of 30° to 45° with respect to a normal to the surface. This relatively high angle can allow the dopants to be efficiently injected into the sides (also referred to as sidewalls) of the trenches. The STI etch typically creates trenches (e.g. holes) having sloped sidewalls. The second angle may be in the range of 0° to 15° with respect to a normal to the surface. This relatively small angle is used to dope the substantially flat bottom of the trenches. The first, second and fifth doping may also be performed by injecting dopants having an injection angle in the range of 0° to 15° to the normal (where 0° means injection perpendicular to the surface of the semiconductor wafer). At least the third doping and preferably all doping steps can be performed at four or more different rotation angles about a normal to the surface of the wafer. This can provide a more uniform doping in three dimensions when the injection angle is >0°. In some embodiment, six different (preferably equidistant) rotation angles are used (e.g. at 0°, 60°, 120°, 180°, 240°, 300°).

The third doping may comprise injecting the dopants with a first injection energy, while the fourth doping comprises injecting the dopants with a second injection energy, and wherein the first injection energy is greater than the second injection energy. For example, the first injection energy may be in the range of 20 keV to 30 keV, and the second injection energy may be in the range of 10 keV to 25 keV. The dopants for the third and fourth doping may be BF2 molecules.

The first doping may comprise injecting dopants with an injection energy in the range of 2 MeV to 3 MeV. The dopants may be P atoms. The second doping may comprise injecting dopants with an injection energy in the range of 10 keV to 20 keV. The dopants may be B atoms. The fifth doping may comprise injecting dopants with an injection energy in the range of 10 keV to 20 keV. The dopants may be B atoms.

The second, third, fourth and fifth doping steps can be performed using the same mask. The second, third, fourth and fifth doping steps are performed so as to create a continuously falling doping concentration from the trenches to the pn-junction. This can reduce the risk of charge carriers getting trapped or otherwise not reaching the pn-junction for detection.

The semiconductor wafer is typically a silicon wafer comprising an epitaxial layer within which the first well and the second well are formed. In other embodiments, the wafer may be a SOI wafer comprising an epitaxial silicon layer on a buried oxide layer.

The method may further comprise forming a backend stack comprising a plurality of metal layers separated by interdielectric layers, and a nitride passivation layer, and locally removing the nitride passivation layer in a region overlapping the pn-junction (to create a so called UV window).

The trenches may comprise circular or hexagonal holes having a width in the range of 220 nm to 350 nm and a spacing from an adjacent hole in the range of 70 nm to 210 nm. In an alternative embodiment, the trenches may define raised portions (e.g. pillars or spikes) of semiconductor material left in the light sensitive region. The method may further comprise filling the trenches with silicon oxide to form a layer of an effective medium at the surface of the wafer, wherein the effective medium has a wavelength dependent refractive index n between the refractive index of silicon oxide and silicon. An optimal refractive index of the effective medium can be calculated by

$${n}_{1} = \sqrt{{n}_{0} \cdot {n}_{2}} ,$$

Wherein n0 and n2 are the refractive indices of the two materials on either side of the effective medium (in this case silicon oxide and silicon respectively). Using the second material (silicon) in forming the effective medium as described herein can be particularly advantageous for forming an effective anti-reflective coating (ARC) layer, as the refractive index of the effective medium will change substantially along with that of the second material. That is the effective medium can have similar wavelength dependence to that of the underlying material.

Also described herein is a semiconductor structure comprising a photodiode formed according to the method described above, and a sensor comprising a plurality of such photodiodes.

A particular advantage of the photodiode may be the increased sensitivity in the UVC range (about 100 nm to 280 nm wavelength) against state-of-the-art CMOS integrated devices and high performance discrete devices. Accordingly, an advantage is the ability to detect weaker signals or to save chip area as the active sensor area can be half as large for the same response and results in half capacitance. The smaller area can also provide a smaller dark current. Another advantage can be that less light is reflected and the collection volume of the device is smaller, so it is less receptive to noise and potentially faster, it may also have a higher linearity range, as the internal resistance is smaller for a similar photocurrent compared to conventional devices.

Embodiments have shown an increased reliability of the response of photodiodes against UV light stress. While most silicon based UV detectors suffer strong degradation from UV light exposure, photodiodes formed according to the described method have shown a significant decrease in such degradation. Hence, the photodiodes can perform well under UV light with little to no measurable degradation.

Generally, silicon based photodiodes may be less sensitive to light in the UVC range (100 to 280 nm) than to light in the UVB (280 to 315 nm), UVA (315 to 400 nm) and the visible range (400 to 800 nm). This can be problematic in low light applications, where the low intensity of the signal of interest results in a small photocurrent and thereby a small output signal of the photodiode. In this case, it can be difficult to determine the signal of interest accurately (e.g. to distinguish the signal of interest from noise in the output signal) for two reasons. Firstly, even small amounts of stray light in the UVA, UVB or visible range can contribute to a large noise level in the output signal (due to the higher sensitivity of the photodiode in this spectral range). Secondly, noise caused by the (temperature-dependent) dark current of the photodiode (i.e. the leakage current that flows when a bias voltage is applied to the photodiode) can further obscure the signal (i.e. the current produced by the incident light of interest).

It is known that the noise level of the output signal of the photodiode can be improved by subtracting the current of a dark reference device from the current of the photodiode. The dark reference device is typically a similar photodiode (thus providing a dark current with a similar temperature dependency as the primary photodiode) which is insensitive to light. Thus, the dark reference device can be identical to the primary photodiode but provided with a light shield (e.g. a metal layer) to prevent light from reaching the optical sensitive area. For light sensing applications in the UVA and UVB range (280 to 400 nm), the optical sensitive area of the reference device may be covered with a thin layer (typically between 100 and 400 nm thick) of polysilicon (as part of the CMOS manufacturing process) instead of a metal layer. This has the effect that the reference photodiode is no longer “dark” (i.e. shielded from all light) but detects the unwanted stray light in visible and near-infrared part of the optical spectrum (i.e. light with wavelengths larger than 400 nm). This is because the relatively thin polysilicon layer exhibits typically moderate optical absorption for light in the visible and near-infrared range (e.g. 400 to 1100 nm), and strong optical absorption for UV light (i.e. a polysilicon layer can be transparent or translucent visible and near-infrared light, and essentially opaque for UV light). Thus, subtracting the current of the reference diode from the current of the primary photodiode corrects the output signal not only for the dark current but also for the photocurrent caused by visible and near-infrared stray light, thereby improving the UV-light detection accuracy.

However, the above described approach may be insufficient when the signal of interest is in the UVC range (100 to 280 nm). This is because the above described approach does not correct for stray light in the UVA and UVB range (280 to 400 nm), since the polysilicon layer shields the (optical sensitive area of the) reference diode from UVA and UVB light. Thus, it is desirable to provide an optical sensor which overcomes these problems of conventional optical sensors and enables the detection of low intensity signals in the UVC range of the optical spectrum. Such an optical sensor is described with reference to FIGS. 7 to 10.

In general, embodiments described herein provide an optical sensor comprising a “primary” and a “reference” photodiode. The primary photodiode and the reference photodiode are substantially identical except that the reference photodiode comprises a light shield covering its optical sensitive area. In particular, the light shield of the reference photodiode is configured to be substantially transparent to UVA, UVB, visible and near-infrared light, and to prevent (or substantially attenuate) UVC light from entering the optical active area (i.e. to prevent any light induced charge carriers). In particular, the light shield of the reference photodiode may be implemented as a wavelength-selective absorption layer configured to exhibit low optical absorption in a wavelength range of 300 to 1100 nm, and high optical absorption in a wavelength range of 200 to 275 nm. As described in detail below, this light shield may conveniently be implemented by a silicon nitride passivation layer.

In the embodiment shown in FIG. 7, an optical sensor 42 comprises, as a primary photodiode, the photodiode 2 as described above with reference to FIGS. 1 to 6, and a reference photodiode 44. The optical sensor 42 is configured to determine a light level of incident light based on a difference between the electrical current generated by the reference photodiode 44 and the electrical current generated by the primary photodiode 2. To this end, the optical sensor 42 may further comprise circuitry 48 connected to the photodiodes 2, 44, and configured to determine a difference between the currents generated by the photodiode 2, 44 (e.g. by subtracting the current generated by the reference photodiode 44 from the current generated by the primary photodiode 2) and to provide an output signal based on the determined difference. Any known suitable design may be used to implement the circuitry 48. As described in detail below, the optical sensor 42 may be particularly well suited for sensing UVC light, and in particular light in a wavelength range of 200 to 275 nm.

In general, the optical sensor 42 is a CMOS integrated circuit device. The primary and the reference photodiode 2, 44 may be formed on the same semiconductor wafer. Typically, the primary and the reference photodiode 2, 44 are formed close to each other (e.g. directly adjacent), such that both photodiodes experience substantially the same (amount of) stray light and operate at substantially the same temperature. This may have the effect that noise caused dark currents and stray light can be efficiently corrected. Whilst the embodiment of FIG. 7 includes only one primary and one reference photodiode 2, 44, it is understood that other embodiments may comprise a plurality of primary photodiodes and a (corresponding) plurality of reference photodiodes. In this case, the photodiodes may be arranged in a regular array (e.g. in a one or two-dimensional array) such that instances of primary and reference photodiodes alternate.

FIG. 8 shows a schematic cross section of the reference photodiode 44. The reference photodiode 44 is a variation on the photodiode 2 of FIG. 1, and to avoid unnecessary repetition, like reference numerals will be used to denote like features. Like the primary photodiode 2 of FIG. 1, the reference photodiode 44 of FIG. 8 comprises a backend stack 24 which comprises a passivation layer 46. However, in contrast to the primary photodiode 2, the backend stack 24 of the reference photodiode 44 does not comprise the UV window 28. Instead, the passivation layer 46 of the backend stack 24 of the reference photodiode 44 overlaps the light sensitive area of the photodiode. Thus, the passivation layer 46 may be a featureless layer covering the entire backend of the reference photodiode 44. The passivation layer 46 of the reference photodiode 44 may comprise silicon nitride (e.g. the passivation layer 46 may be made of silicon nitride).

In the embodiment of FIG. 8, the silicon nitride comprising passivation layer 46 acts as the aforementioned light shield of the reference photodiode 44. Thus, firstly, the passivation layer 46 shields the light sensitive area of the reference photodiode 44 from incident UVC light since silicon nitride exhibits strong optical absorption for UVC light, i.e. incident UVC light is blocked (or at least substantially attenuated) by the passivation layer 46. Secondly, the passivation layer 46 is substantially transparent for light in the range of 300 to 1100 nm (i.e. UVA, UVB, visible and near-infrared light), thereby allowing such light to enter the light sensitive area of the reference photodiode 44 and create light induced charge carriers.

The reference photodiode 44 may be formed according to the method of forming the primary photodiode 2 described above, except that no step of removing the nitride passivation layer for forming the UV window 28 is required. Thus, a particular advantage of the reference photodiode 44 of FIG. 8 may be that the reference photodiode 44 can be fabricated using CMOS processes and without requiring additional steps compared to the primary photodiode 2 (the reference photodiode may need fewer fabrication steps since the UV window 28 is not formed). This makes it possible to form the optical sensor 42 in a cost effective manner.

It is understood that in embodiments where the primary photodiode 2 and the reference photodiode 44 are formed on the same semiconductor wafer (e.g. adjacent to each other), the passivation layer 26 of the primary photodiode 2 and the passivation layer 46 of the reference photodiode 44 may be formed in the same process step (i.e. as a single layer), and may be formed as an outermost encapsulating protective layer of the optical sensor.

In general, the material and the thickness of the layer 46 may be selected such that an optical transmission of the layer 46 is less than 70% in a wavelength range of 200 to 275 nm. Additionally or alternatively, the material and the thickness of the layer 46 may be selected such that the optical transmission of the layer 46 is greater than 70% in a wavelength range of 300 to 1100 nm. For example, in an embodiment where the passivation layer 46 of the reference photodiode 44 is made of silicon nitride, the thickness of the passivation layer 46 may be in the range of 300 to 1000 nm.

Experimentally, it has been found that embodiments of the reference diode 44 exhibit a dark current which is approximately 40% lower than the dark current of the primary photodiode 2. This has the effect that, in the absence of any incident light, subtracting the current of the reference diode 44 from the current of the primary diode 2 results in a positive current. This is beneficial compared to the case where the reference photodiode exhibits the same average dark current as the primary photodiode because the read out circuitry may fail when the direction of the subtracted current (randomly) changes (because the dark current of the reference photodiode is sometimes larger and sometimes smaller than the dark current of the primary photodiode). Further, it has been found that the responsivity of the reference photodiode 44 is approximately 10% lower across a spectral range of 200 nm to 1100 nm than the responsivity of the primary photodiode 2, thus also in the presence of light, negative currents are generally prevented.

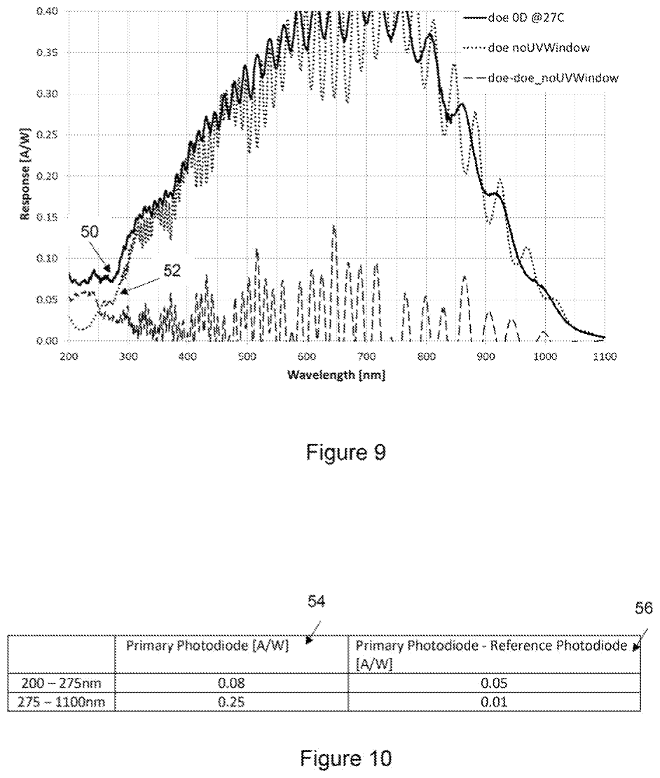

Further experimentally obtained data is described with reference to FIGS. 9 and 10. FIG. 9 shows a graph illustrating the respective responsivities 50, 52 of the primary photodiode 2 and the reference photodiode 44 over a spectral range of 200 nm to 1100 nm. As shown in FIG. 9, the responsivity 50 of the primary photodiode 2 is substantially higher than the responsivity 52 of the reference photodiode 44 in a range of 200 to 275 nm (because the nitride passivation layer 46 absorbs strongly in this range). The responsivities 50, 52 are however substantially equal over a range of 275 to 1100 nm (the average responsivity of the reference photodiode may be 10% lower). Thus, because both photodiodes have substantially the same responsivity over the range of 275 to 1100 nm, subtracting the respective currents removes the contributions of any stray light in this spectral range from the output signal of the optical sensor 42. It is understood that the benefits of accurately removing the stray light contributions often outweigh drawbacks caused by a small, residual sensitivity of the reference photodiode 44 to light in the target range (i.e. 200 to 275 nm). In other words, a small but noise-free signal is typically acceptable (i.e. such a signal may have a better signal to noise ratio than a larger signal on top of a large noise level).

FIG. 10 shows a table with experimentally obtained values. Column 54 shows the average responsivities of the primary photodiode 2 respectively over the spectral ranges of 200 to 275 nm and 275 to 1100 nm. Column 56 shows the corresponding responsivities when the responsivity of the reference photodiode 44 is subtracted from the responsivity of the primary photodiode 2 (thus the values of column 56 correspond to the effective responsivity of the optical sensor 42). Thus, by the subtracting the currents of the two photodiodes 2, 44, the responsivity of the optical sensor 42 is reduced from 0.25 A/W to 0.01 A/W for the (stray) light range of 275 to 1100 nm. In other words, the output of the optical sensor 42 is substantially insensitive to light in this range. The optical sensor 42 is however sensitive to light in the (target) range of 200 to 275 nm where the average responsivity of the optical sensor 42 is reduced from 0.08 A/W to 0.05 A/W by subtracting the currents of the photodiodes 2, 44 (this reduction is due to the dark current cancelation and the residual sensitivity of the reference photodiode 44 to light in the target range). Thus, the optical sensor 42 is sensitive to light in the UVC range while being substantially insensitive to stray light (in the UVB, UVA, visible and near-infrared range) and to temperature variations (because both photodiodes 2, 44 have dark currents with the same temperature dependency). The optical sensor 42 mitigates therefore the need for costly and bulky optical filters to reduce the noise level caused by stray light.

While specific embodiments of the invention have been described above, it will be appreciated that the invention may be practiced otherwise than as described. The descriptions above are intended to be illustrative, not limiting. It will be apparent to one skilled in the art that modifications may be made to the invention as described without departing from the scope of the claims set out below.

Each feature disclosed or illustrated in the present specification may be incorporated in the invention, whether alone or in any appropriate combination with any other feature disclosed or illustrated herein.

1. An optical sensor comprising:
a first photodiode and a second photodiode, each photodiode comprising a respective light sensitive area, the second photodiode further comprising a wavelength-selective absorption layer arranged to selectively attenuate incident light before the light enters the respective light sensitive area of the second photodiode, the wavelength-selective absorption layer characterized by a low optical absorption in a wavelength range of 300 to 1100 nanometers (nm) and a high optical absorption in a wavelength range of 200 to 275 nm,
wherein the first photodiode and the second photodiode are configured to generate respective electrical currents in response to the incident light, and the optical sensor is configured to determine a light level based on a difference between an electrical current generated by the first photodiode and an electrical current generated by the second photodiode.

2. The optical sensor of claim 1, wherein the wavelength-selective absorption layer is an electrically insulating passivation layer.

3. The optical sensor of claim 2, wherein the electrically insulating passivation layer comprises silicon nitride.

4. The optical sensor of claim 3, wherein the electrically insulating passivation layer is made of silicon nitride.

5. The optical sensor of claim 1, wherein an optical transmission of the wavelength-selective absorption layer is less than 70% in a wavelength range of 200 to 275 nm.

6. The optical sensor of claim 1, wherein an optical transmission of the wavelength-selective absorption layer is greater than 70% in a wavelength range of 300 to 1100 nm.

7. The optical sensor of claim 1, wherein the first and the second photodiodes are formed in a same semiconductor layer of a semiconductor wafer using a complementary metal oxide semiconductor process.

8. The optical sensor of claim 7, wherein the wavelength-selective absorption layer is an outermost encapsulating protective layer of the optical sensor.

9. The optical sensor of claim 1, further comprising circuitry for producing a difference signal corresponding to said difference between the electrical current generated by the first photodiode and the electrical current generated by the second photodiode.

10. A method of forming an optical sensor, the method comprising:
providing a semiconductor wafer comprising a semiconductor layer;
forming, in the semiconductor layer, a first photodiode comprising a first light sensitive area; and
forming, in the semiconductor layer, a second photodiode comprising a second light sensitive area and a wavelength-selective absorption layer arranged to selectively attenuate incident light before the incident light enters the light sensitive area of the second photodiode, wherein the wavelength-selective absorption layer is characterized by a low optical absorption in a wavelength range of 300 to 1100 nanometers (nm) and a high optical absorption in a wavelength range of 200 to 275 nm, and wherein the first photodiode and the second photodiode are formed to, when in use, generate respective electrical currents in response to the incident light, and the optical sensor is configured to, when in use, determine a light level based on a discrepancy between the electrical current generated by the first photodiode and the electrical current generated by the second photodiode.

11. The method of claim 10, wherein each of the first photodiode and the second photodiode is formed by:
performing a first doping step to form a first well in the semiconductor layer having a first type of doping;
performing a second doping step to form a second well having a second type of doping, so as to form a pn-junction of the first photodiode or the second photodiode between the first well and the second well;
performing a shallow trench isolation etch to form a plurality of trenches in a surface of the semiconductor layer in the second well;
performing a third doping step by injecting dopants at a first angle relative to the surface of the semiconductor wafer in order to increase a doping concentration of the second type of doping at along sides of the plurality of trenches in the second well;
performing a fourth doping step by injecting dopants at a second angle relative to the surface of the semiconductor wafer in order to increase a doping concentration of the second type of doping at a bottom of the plurality of trenches in the second well;
performing a fifth doping step to increase a doping concentration of the second type of doping at the surface of the semiconductor layer between the plurality of trenches in the second well;
forming a first contact for contacting the first well and forming a second contact for contacting the second well in order to apply a voltage across the pn-junction when in use; and
forming a backend stack comprising a plurality of metal layers separated by interdielectric layers, and the wavelength-selective absorption layer,
wherein forming the second photodiode further comprises locally removing the wavelength-selective absorption layer in a region overlapping the pn-junction.

12. The method of claim 10, wherein each of the first photodiode and the second photodiode is formed by:
performing a first doping step to form a first well in the semiconductor layer having a first type of doping;
performing a second doping step to form a second well having a second type of doping, so as to form a pn-junction of the first photodiode or the second photodiode between the first well and the second well;
performing a shallow trench isolation etch to form a plurality of raised portions of semiconductor material in a surface of the semiconductor layer in the second well;
performing a third doping step by injecting dopants at a first angle relative to the surface of the semiconductor wafer in order to increase a doping concentration of the second type of doping at along sides of the plurality of raised portions in the second well;
performing a fourth doping step by injecting dopants at a second angle relative to the surface of the semiconductor wafer in order to increase a doping concentration of the second type of doping between the plurality of raised portions in the second well;
performing a fifth doping step to increase a doping concentration of the second type of doping at the surface of the semiconductor layer at a top of the plurality of raised portions in the second well;
forming a first contact for contacting the first well and forming a second contact for contacting the second well in order to apply a voltage across the pn-junction when in use; and
forming a backend stack comprising a plurality of metal layers separated by interdielectric layers, and the wavelength-selective absorption layer,
wherein said forming the second photodiode further comprises locally removing the wavelength-selective absorption layer in a region overlapping the pn-junction.

13. The method of claim 10, wherein the wavelength-selective absorption layer is an electrically insulating passivation layer.

14. The method of claim 13, wherein the electrically insulating passivation layer comprises silicon nitride.

15. The method of claim 14, wherein the electrically insulating passivation layer is made of silicon nitride.

16. The method of claim 10, wherein an optical transmission of the wavelength-selective absorption layer is less than 70% in a wavelength range of 200 to 275 nm.

17. The method of claim 10, wherein an optical transmission of the wavelength-selective absorption layer is greater than 70% in a wavelength range of 300 to 1100 nm.
